(19) United States
(12) Patent Application Publication
(10) Pub. No.: US 2006/0031032 A1
(43) Pub. Date: Feb. 9, 2006

(54) Method and apparatus for reducing skew effects

(76) Inventor: Robert C. Cohn, Beaverton, OR (US)

Correspondence Address: Thomas F. Lenihan;Tektronix, Inc., M/S 50-LAW, P.O. Box 500, Beaverton, OR, 97077-0001, US

(21) Appl. No.: 10/912,900

(22) Filed: Aug. 6, 2004

(51) Int. Cl. G01R 13/00

(52) U.S. Cl. 702/69

(57) ABSTRACT

Method for deskewing sampled data includes acquiring data samples from a first location in a first channel according to a first set of data collection parameters, performing a validity analysis of the acquired data samples, and in response to the occurrence of a trigger condition, halting the acquisition of new data samples from the first location, adjusting at least one of the first set of parameters and initiating the acquisition of data samples from a second location in the first channel. An interactive completion signal subsequent to data acquisition provides selection of optimal sampling points in the first channel for further data collection.

### FIELD OF THE INVENTION

The invention relates generally to signal acquisition systems and, more particularly, to a method and apparatus for selecting optimal sampling points in a logic analyzer.

### BACKGROUND OF THE INVENTION

Signal acquisition devices such as logic analyzers (LAs) are instruments used for verifying and debugging digital circuits. A logic analyzer verifies that a digital circuit is working and provides information for troubleshooting such a circuit. The logic analyzer is capable of capturing and displaying many signals of the digital circuit at one time and analyzing their timing relationships. Since timing relationships in digital circuits are paramount to their correct functioning, determining optimal sampling points for capturing such information in a logic analyzer is necessary for proper troubleshooting and problem diagnosis. Optimal sampling points are determined by a relationship between desired signals and an externally supplied clock. If the time that a data sample is acquired by the logic analyzer (according to the external clock) does not coincide with a time that a signal under test (SUT) is stable, such a condition will introduce skewing effects (i.e., invalid data) in the resultant output. It is therefore important to conduct data valid window analysis (DVWA) to find the optimal data sampling point in the SUT relative to the external clock transition to obtain valid data.

FIG. 1 shows an example of a channel 102 of a LA that has at least one DVW around a clock transition 110. Specifically, Data Invalid Windows (DIWs) 104 in which the channel 102 is not stable (has varying values), and one Data Valid Window (DVW) 106 in which the channel 102 has a constant value are depicted. The DVW 106 (which could be one of many on the channel) satisfies the requirement for the channel 102 to be stable within the setup (tₛₑₜᵤₚ) and hold (t_{hold}) times of the external clock transition 110.

The LA samples data at a very high resolution. This allows a user to visually inspect a channel's data in a waveform display and, with much effort, visually determine whether the channel's data is stable with respect to a clock transition. Visual determination requires a user to inspect adjacent data sample points for same values because two adjacent values that are the same (i.e., a logical 1 or 0) value indicate data stability. This operation may involve taking many LA data acquisitions or it may require inspection of many clock transitions within a single acquisition, depending on the nature of the channels and clocks being used. If data stability is not obtained, then the user must manually make incremental adjustments to the LA's sampling tₛₑₜᵤₚ and t_{hold} parameters for a signal to sample data for correct DVW results. This is a tedious operation when many channels must be compared and adjusted. FIG. 2 shows an example of a channel 102 with stable data values 112 around the clock transition 110 selected from a plurality of possible sample points 108. The LA's setup and hold sampling point for the channel 102 has been adjusted so that stable data can be obtained with respect to the external clock transition.

One way to determine data stability on a channel is to see where the high resolution data is stable with respect to a clock edge. Another way to determine data stability is to run an LA trigger program that checks for data setup and hold violations within a specified range and then triggers if a violation is found. A trigger program is a set of directions to the LA acquisition hardware indicating actions to be taken when a data event of interest is detected. When the LA executes a trigger program during a data acquisition, the resulting set of acquisition samples satisifies the logic conditions of the program. In most cases, the trigger program directs the acquisitions to stop (or complete the filling up of a data buffer) when an event of interest (for example, a violation of a setup and hold parameter ranges) is detected. One drawback of having to use a trigger program is that it may require many iterations of setup and hold adjustments and data acquisitions before a DVW can be determined for one channel. The problem is multiplied when many channels have to be so evaluated.

### SUMMARY OF INVENTION

Various deficiencies in the prior art are addressed by the present invention of a method and apparatus for deskewing sampled data. The method in one embodiment includes the steps of (a) acquiring data samples from a first location in a first channel according to a first set of data collection parameters, (b) performing a validity analysis of the collected data samples and (c) upon a trigger parameter reaching a predetermined value, halting the acquisition of new data samples from the first location, adjusting a value of one or more of the first set of parameters, acquiring data samples from a second location in the first channel. Subsequently, an interactive completion of data acquisition signal is sent that provides selection of optimal sampling points for all analyzed channels for further data collection. In one embodiment of the invention, the validity analysis is a Data Valid Window analysis. In another embodiment of the invention, the validity analysis is a setup/hold violation analysis. The step of adjusting a value of one or more of the first set of parameters further comprises adding a time ΔT to a setup variable and a hold variable.

### BRIEF DESCRIPTION OF THE DRAWINGS

The teachings of the present invention can be readily understood by considering the following detailed description in conjunction with the accompanying drawings, in which:

FIG. 1 depicts a timing diagram of an existing logic analyzer clock and a corresponding logic analyzer channel showing valid and invalid windows for collecting data;

FIG. 2 depicts a timing diagram and corresponding channel showing signal values in the channel of an existing logic analyzer and available sample points for collecting data in the channel;

FIG. 3 depicts a series of method steps for reducing the skew effects introduced by data signals in a channel in accordance with the subject invention;

FIG. 4 depicts first view of a user interface in accordance with the subject invention;

FIG. 5 depicts an apparatus for reducing the skew effects introduced by data signals in a channel in accordance with the subject invention; and

FIG. 6 depicts a second view of the skew effects introduced by data signals in a channel in accordance with the subject invention.

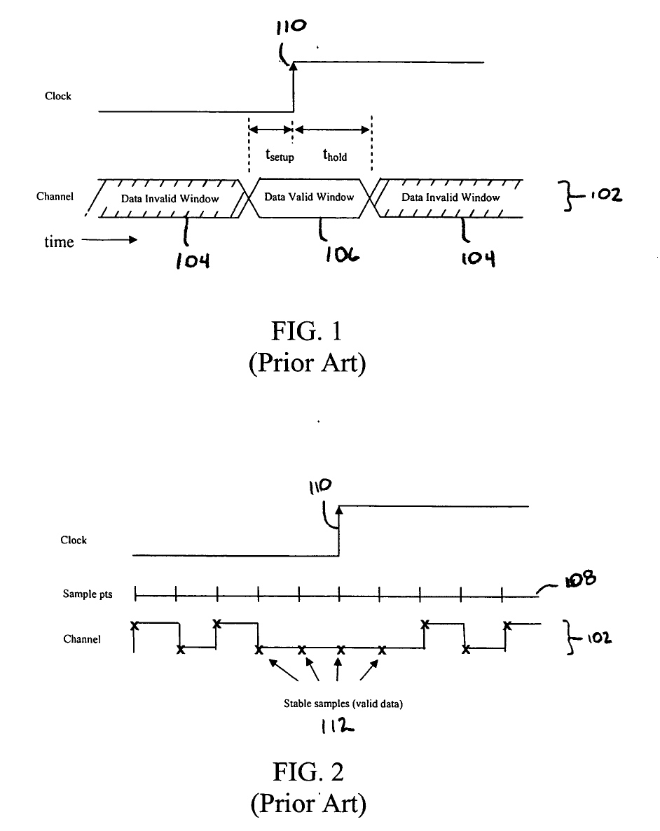

To facilitate understanding, identical reference numerals have been used, where possible, to designate identical elements that are common to the figures.

### DETAILED DESCRIPTION OF THE INVENTION

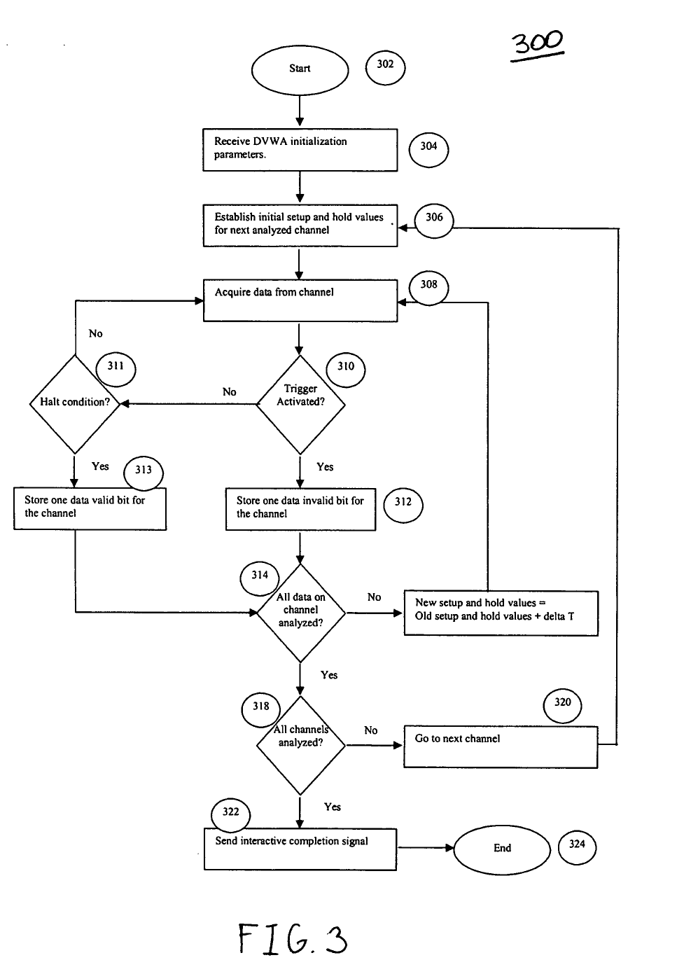

The subject invention provides for improved circuitry and operational methods for reducing the skew effects introduced by SUTs when under observation by, for example, LAs. Generally speaking, the invention performs automatic searches for DVWs in an operational mode denoted as Data Valid Window Analysis (DVWA). The results of DVWA show regions of stability and instability relative to a clock edge for each channel analyzed. Upon DVWA completion, the invention automatically selects a suggested sampling point for each analyzed channel and lets a user optionally apply that sampling point to tₛₑₜᵤₚ and t_{hold} for that channel in any of the LA's synchronous clocking modes. The sampling point is considered to be the approximate center of a small setup/hold window that represents what the LA considers to be the setup and hold conditions at its probe tip for a channel. The invention picks the setup/hold window containing the suggested sampling point and sets that channel's tₛₑₜᵤₚ and t_{hold} values. The user has the flexibility of changing the suggested sampling point (e.g., he can move the suggested sampling point into another DVW if desired). FIG. 3 depicts a flow diagram of a deskewing method 300. The method starts at step 302 and proceeds to step 304 where initialization parameters for DVWA are received. In one embodiment of the invention, a user provides such parameters via a user interface that is interacting in accordance with the method. In one embodiment, initialization parameters include one or more of the following: what type of analysis is to be performed, which instrument is being analyzed, which channel(s) is being analyzed on the selected instrument, the channel(s) to be used for clocking, the range over which the analysis will take place and a quality number which is used to determine the extent to which data acquisition for the method is conducted.

At step 306, three additional values are established for conducting the SUT analysis. In one embodiment of the subject invention, values for parameters tₛₑₜᵤₚ and t_{hold} that signify the relationship of the time surrounding a clock signal in the logic analyzer are set at a first extreme of an analysis range. Additionally, a trigger program is set to a first state to monitor data acquisition activity by looking for setup and hold violations. Once these initial states and values are established, the method proceeds to step 308, where the process of acquiring data from a channel being analyzed is performed. The process of acquiring data is known to those skilled in the art and can be found, for example, in “The XYZs of Logic Analyzers”, Sep. 20, 2002 by Tektronix, Inc. of Beaverton, Oreg. An exemplary method of calculating DVWs may be found at “High Speed State-Analyzer Measurements Call For Precise Sample Positioning” by Sontag and Nygaard and “Debugging the wireless boundary shift” by Woodward and Herron, all of which are herein incorporated by reference in their entireties.

Once data is acquired at a given clock sample, the method proceeds to step 310 where a first decision process is performed. Specifically, this first process evaluates whether a trigger event has occurred during the data acquisition period. Trigger activation occurs by the detection of a set up/hold violation. If a trigger event (i.e., a setup/hold violation) has activated the trigger of first decision step 310, then the method proceeds to step 312 where information regarding an invalid data window is stored. In one embodiment of the invention, one data invalid bit for the analyzed channel is stored.

If a trigger event does not occur during the analysis, then the method proceeds from the first decision step 310 to a second decision step 311 where channel analysis halt conditions are determined. Specifically, at step 311 the method takes additional factors into consideration when analyzing channels that include one or more of the following: detecting a timeout condition, suspension of the analysis by a user “abort” command and determining if the number of data acquisition samples has exceeded a user-defined quality value (one of the initialization parameters defined in step 304). If any of the halt conditions occur, channel analysis is halted and the method proceeds to step 313 where information regarding a valid data window is stored. In one embodiment of the invention, one data valid bit for the analyzed channel is stored. If none of the halt conditions occur, the method loops back to step 308 where another data sample is acquired at a subsequent sample point.

In one embodiment of the invention discussed in detail below, bits that encode the results of valid and invalid data samples are stored as four 32-bit integers (for a total of 128 bits). Such integers are processed into a list of DVWs for each channel and ultimately sent to a user interface (explained in greater detail below) for display to the user.

Once DVW information is stored, the method proceeds to step 314 where a third decision step occurs. This third decision step 314 determines whether all data on a particular channel has been analyzed. If the answer to this query is negative, the method proceeds to step 316 where updated tₛₑₜᵤₚ and t_{hold} values are determined. In one embodiment, new tₛₑₜᵤₚ and t_{hold} values are determined by adding a time interval ΔT, where ΔT represents the time shift necessary to analyze the next set of samples away from the original tₛₑₜᵤₚ and t_{hold} extremity values. In one embodiment, the original tₛₑₜᵤₚ and t_{hold} values are at one extreme of the analysis range (i.e., a furthest point in the analysis range after a clock pulse) and the ΔT moves the sampled value temporally through the analysis range (i.e., to a furthest point in the analysis range prior to the clock pulse). Once the new tₛₑₜᵤₚ and t_{hold} values are established, the method loops back to step 308 where data acquisition and DVW calculations are performed for the new samples until such time that another trigger event is activated as described earlier in step 310.

If all data on a particular channel has been analyzed, the query to third decision step 314 is answered positively and the method proceeds to step 318, where a fourth decision step is performed. Specifically, fourth decision step 318 inquires as to whether all channels that are desired to be analyzed have, in fact, been analyzed. If additional channels are to be analyzed, then the method proceeds to step 320 where the next channel to be analyzed is selected. Subsequently, the method loops back up to step 306 where tₛₑₜᵤₚ and t_{hold} values and the trigger state are established for the new channel (i.e., at the furthest point in the analysis range after a clock pulse) and the acquisition and subsequent triggering evaluations are performed for the new channel until such time that trigger and data analysis events on that channel are completed in accordance with the steps described above.

If additional channels are not to be analyzed, the method proceeds to step 322 whereby an interactive completion signal is sent to a user. In one embodiment of the invention, the interactive completion signal allows the user to view the results of the DVW calculations and overall analysis and decide whether to accept (and subsequently readjust sample points in each of the DVWs) or whether to allow the analysis to continue with preselected data points. The method ends at step 324. Note that while the subject method has been discussed and presented as occurring in real-time, it is also possible to collect all data samples from all channels and store such information for processing and analyzing at a time decided upon by the user before collecting additional data based on the optional sampling points in each channel.

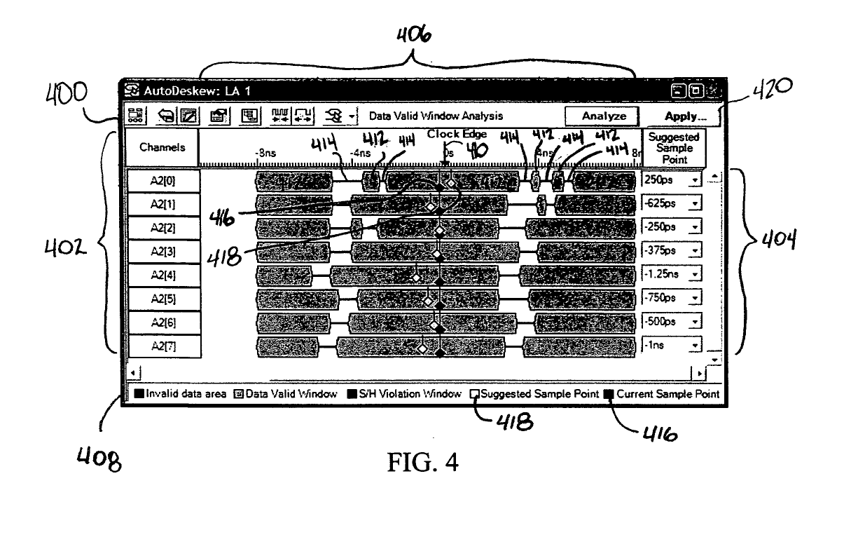

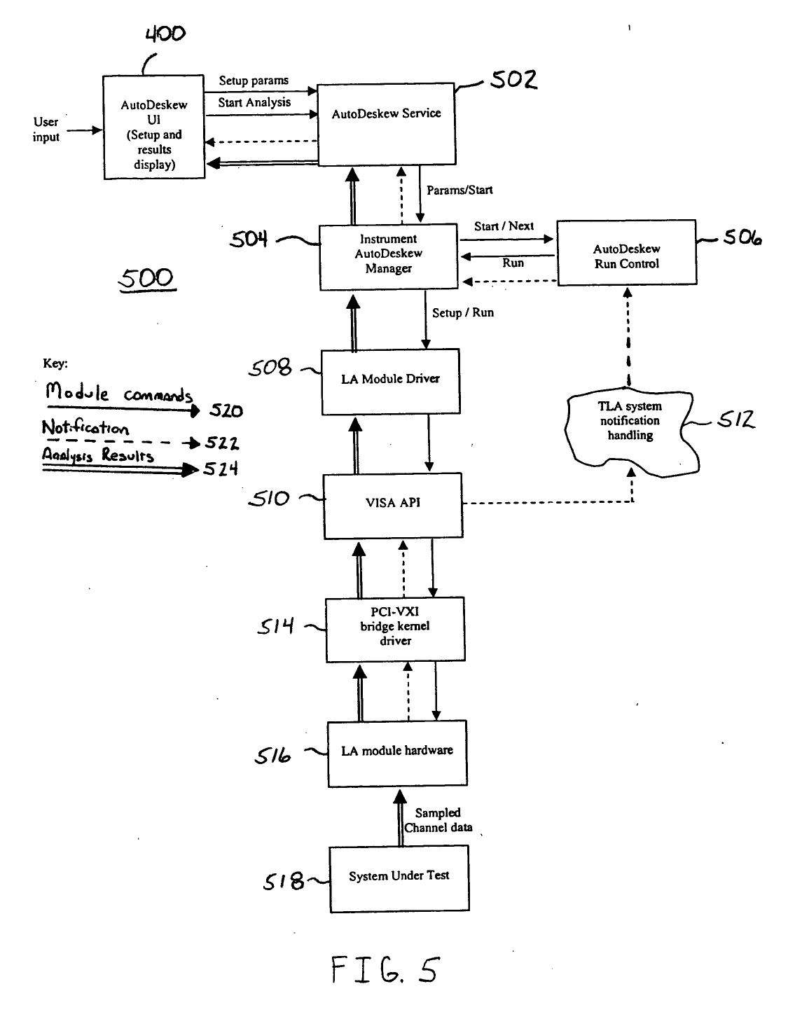

FIG. 4 depicts an exemplary user interface display 400 suitable for use in practicing the subject method 300. User interface display 400 is shown as a specific task window in a Microsoft Windows-based operating environment of a computer or display apparatus associated with a logic analyzer. One skilled in the art would realize that different types of display scenarios are possible without affecting or otherwise changing the scope of the invention. The user interface display 400 further includes a plurality of subsections that provide additional information regarding the DVWA results. Specifically, a first field 402 depicts the number of channels that were analyzed during the DVWA. A second field 404 depicts a numerical representation of the results of the DVWA analysis for each of the channels depicted in first field 402. A third field 406 depicts a graphical representation of the DVWA and a fourth field 408 depicts a key for the graphical representation field 406.

In key 408, the Invalid Data Area block may be black, the Data Valid Window block may be colored blue, the S/H Violation block may be colored magenta, the Suggested Sample Point block may be colored yellow, and the Current Sample Point block may be colored green. Corresponding areas in Screen Display 400 are displayed in corresponding colors. For example, all Data Valid Window areas 412 are displayed in blue, and all Suggested Sample Points 418 are displayed in yellow.

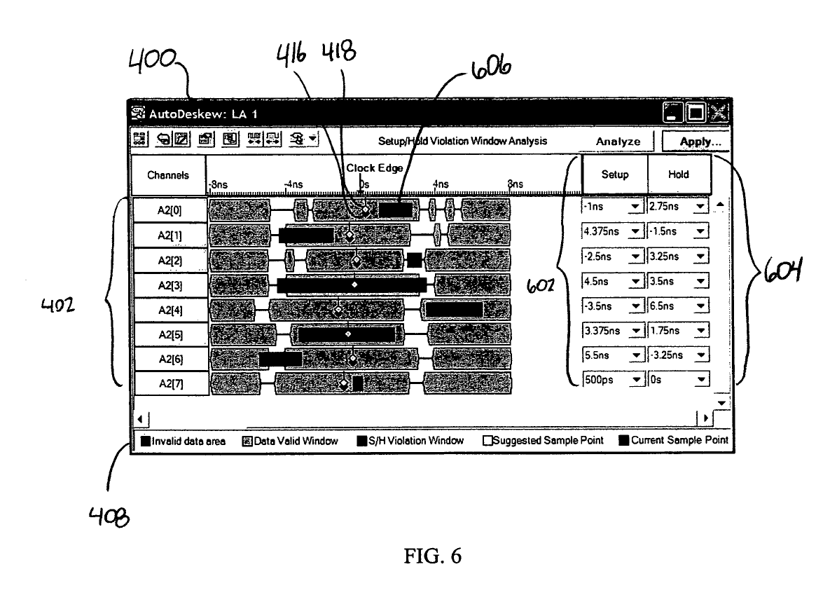

In this figure, eight channels have been analyzed (A2[0] through A2[7]) (depicted in first field 402) in a range between 8 ns before the clock edge 410 to 8 ns after clock edge 410. Each channel shows one or more DVWs and DIWs. The valid data areas are denoted as relatively thicker horizontal bars 412, and the invalid data areas are denoted as relatively thinner horizontal lines 414. For sake of clarity, only first channel A2[0] has been labeled with the DVW and DIW legends in the figure. In a center DVW for each channel 412C, a first diamond shaped marker 416 denotes the current setup and hold sample point for a channel. In this example, all current setup and hold sample points for all channels are defaulted to the same point so as to be in vertical alignment. A second diamond marker 418 near the current points 416 represents the suggested sample points selected by the subject method. These points are also represented as numbers in the “Suggested Sample Point” column to the right of the data in third field 404. A user may open a dialog by pressing the “Apply . . . ” button 420 and apply the suggested points to the analyzed channels for a desired synchronous clocking mode. As shown in FIG. 6, after applying the suggested sample points, the first markers 416 will be aligned to the second markers 418 thereby placing the sample points in an optimal position to reduce the skewing effects discussed above.

The method of the subject invention is implemented by passing commands and data through a series of software layers between a user and module acquisition hardware. FIG. 5 depicts an exemplary system 500 for practicing the method 300 of the subject invention. In one embodiment, the system 500 is a LA such as described above. Various types of information pass from one element to another in the system 500. The key in FIG. 5 identifies these various types of information as different line segments drawn between system elements and is described in greater detail below. Specifically, a user enters setup data (such as that described in steps 304 and 306 of method 300 above) through the user interface display 400. Such setup data is selected from the group consisting of: which analysis to perform (DVWA or SHVA (described in greater detail below)), which instrument to analyze, which channel(s) to analyze on the selected instrument, the channel(s) to be used for clocking, the range over which analysis will take place, and an “Analysis Quality” number which is used to determine the extent to which searches for violations are conducted. Note that an “instrument” is a logical construction that may consist of one or more modules. For purposes of this example, we will assume that the instrument consists of just one module. Once the user has entered these parameters into the interface 400, then he presses the Analyze button (420 of FIG. 4) to begin the analysis.

The setup information (identified as Module command information in solid line format 520 in the key) is sent through an AutoDeskew Service module 502, which acts as a shell to communicate with an AutoDeskew Manager module 504 for the selected instrument. The Service module 502 contains code to handle each of the different setups from the interface 400 as well as beginning the analysis and sending various exceptions to various error conditions. The AutoDeskew Manager module 504 manages the received setup information and coordinates DVWA activities. For example, the Manager module 504 keeps track of what kind of analysis is being performed, which channels are being analyzed, the analysis range, the clocking that will be used for analysis, and the analysis quality.

Upon starting analysis, the AutoDeskew Manager module 504 sends a command to the AutoDeskew Run Control module 506. The Run Control module 506 is responsible for responding to completion notifications for each phase of the analysis and then telling the AutoDeskew Manager module 504 to begin the analysis. The AutoDeskew Manager module 504 forwards the setup information and Start command to module hardware for each module that comprises the instrument by invoking the services of a LA Module Driver 508. In this example, a single instrument represented by LA Module hardware 516 is depicted although multiple instruments are within the scope of the application. The LA Module Driver 508 formulates the commands recognized by the LA module hardware 516.

All commands going to, and data results from, the LA module hardware 516 must go through a VISA API layer 510, which manages communications with all such modules on the system. The VISA API layer 510 must communicate with a Windows kernel driver 516 that manages operation of the VXI-PCI bridge, a piece of hardware that provides a path to connect the system VXIbus with a PCI bus containing the system LA modules. The kernel driver provides mechanisms for programming the LA module hardware 516, notifying the application when LA module data operations complete, and returning LA module data results to the LA application. A Windows kernel driver is a software module that controls an attached piece of electronic hardware. Such software can be found on any operating system (Windows and Linux are two examples), although each operating system has its own requirements on how a driver should be designed. A VXI-PCI bridge is a piece of electronic hardware that must provide data transfer and event notification between a PCI bus and a VXI bus, which are two well-known computing bus standards.

Finally, the AutoDeskew setup parameters (analysis type, channels, clocking, quality number, and analysis range) arrive at the LA module hardware 516. The LA module hardware 516 contains special firmware (programming) that implements the AutoDeskew analysis. The LA module hardware 516 is connected through probing (not shown) to a SUT 518 which is the circuit being probed. The LA module hardware 516 uses the setup information to configure itself for sampling data (identified as Results information in double solid line format 524 in the key) through the connected probes.

When the AutoDeskew analysis is completed, the LA module hardware 516 sends a message (identified as Notification information in dashed line format 522 in the key and in one embodiment is a “Notify Done” message) that propagates up through the PCI-VXI bridge kernel driver 514, the VISA API 510 and into a set of Message-handling modules 512. The set of Message-handling modules 512 routes notification messages to the AutoDeskew Run Control module 506. The Run Control module 506 routes the notification messages back to the AutoDeskew Manager module 504. The AutoDeskew Manager module 504 in turn sends a notification message to the AutoDeskew Service module 502, which then alerts the user interface 400 that new data is available. At this point, the user interface 400 queries the Service module 502 for the analysis results, which results in a new stream of commands down through all of the layers to the LA Module 516, and subsequently the results are formatted and passed back to the user interface 400, where they are displayed for the user.

An optional additional feature of the subject invention, a second analysis mode identified as setup/hold violation analysis (SHVA), allows the user to test regions of each channel for setup and hold violations, i.e., the user establishes an automated test to report the stability of specified regions that are alleged to be stable (no violations). For example, if the user applies the results of the most recent DVW analysis to a synchronous clocking setup to get optimal data sampling points, SHV analysis tests the extent of a region around each sampling point for its stability. Zero violations reported indicates stability. FIG. 6 shows the user interface 400 configured for performing SHV analysis. Note that all of the suggested sample points have been applied to the clocking setup/hold (the current markers 416 and suggested markers 418 are aligned). As such, the optimal sampling points are being used for these channels in the synchronous clocking mode selected by the user, and the acquired data should be valid for those sampling points.

As discussed earlier with respect to FIG. 4, FIG. 6 shows a second embodiment of the invention shown as a specific task window in a Windows-based operating environment of a computer or display apparatus associated with a logic analyzer. Further and as discussed above, one skilled in the art would realize that different types of display scenarios are possible without affecting or otherwise changing the scope of the invention. The user interface display 400 for the SHV analysis includes a plurality of subsections that provide additional information. Specifically, a first field 402 displays the same information as discussed earlier with respect to DVWA in FIG. 4 (number of channels analyzed). A second field 602 provides the corresponding values of tₛₑₜᵤₚ for each of the analyzed channels and a third field 604 depicts values for t_{hold} for each of the channels.

The ranges over which Setup and Hold violation tests are performed are denoted by SHV range bars 606 that overlay the DVW 412 and DIW 414 areas (and correspond to the pairs of numbers in the columns to the right). Some SHV range bars 606 are entirely contained within a DVW (such as the bars for channels A2[0], A2[4], A2[5] and A2[7]). Accordingly, SHV analysis should produce no violations for those channels. For the other channels, the SHV range bars 606 are either overlapping into DIW areas 414 or entirely contained within a DIW (such as channel A2[2]). In those cases, violations will be produced from SHV analysis.

To set up for SHV analysis, the user must enter, through the user interface 400, which channels are to be analyzed, the clocking specification (manual or custom), the Setup/Hold violation window search range to be applied to all channels, and, optionally, the number of violations to look for. If the user does enter the optional violation count, then the SHV analysis proceeds until it finds that many violations and then stops. Otherwise, analysis proceeds until the user aborts the operation. Note that the user can manually adjust the Setup/Hold violation window search range for individual channels within the main data area 406.

The advantages of using SHVA instead of previously existing trigger programs are that the setting up of SHVA is easier than having the user set up a trigger program, in that he does not have to write the program. Additionally, the setup and hold violation ranges for each analyzed channel are visually tied to each channel's optimal data sampling point. The user does not have to flip back and forth between a module's clocking setup dialog and a trigger program's setup and hold violation definition dialog to make adjustments in each dialog. Further, the user can easily alternate between DVW and SHV analysis modes using incremental adjustments in the sampling points and setup and hold violation ranges until an optimal set of setup and hold violation ranges is found. These can then be applied and used for subsequent normal data acquisition trigger programs.

Accordingly, the subject method and apparatus automatically detect the optimal sampling points of an SUT to ultimately reduce skewing effects. While the foregoing is directed to the preferred embodiment of the present invention, other and further embodiments of the invention may be devised without departing from the basic scope thereof, and the scope thereof is determined by the claims that follow.

What is claimed is:

1. A method for deskewing sampled data comprising:
(a) acquiring data samples from a first location in a first channel according to a first set of data collection parameters;
(b) performing a validity analysis of said acquired data samples; and
(c) in response to the occurrence of a trigger condition, halting the acquisition of new data samples from the first location, adjusting at least one of the first set of data collection parameters, and initiating the acquisition of data samples from a second location in said first channel.

2. The method of claim 1, wherein steps (a)-(c) are repeated until all data on the first channel is analyzed.

3. The method of claim 2, wherein steps (a)-(c) are repeated for at least a second channel being analyzed.

4. The method of claim 1, further comprising a step (d) of sending an interactive completion of data acquisition signal.

5. The method of claim 4, wherein the interactive completion signal provides for selection of optimal sampling points in at least said first channel for further data collection.

6. The method of claim 1, wherein the validity analysis is a Data Valid Window analysis.

7. The method of claim 6, wherein if the Data Valid Window analysis detects a violation, information regarding an invalid data window is stored.

8. The method of claim 6, wherein if the Data Valid Window analysis does not detect a violation, a halt condition is analyzed.

9. The method of claim 8, wherein if a halt condition is met, information regarding a valid data window is stored.

10. The method of claim 9, wherein if the halt condition is not met, a data sample from a second location in the first channel is acquired.

11. The method of claim 1, wherein the step of adjusting a value of one or more of the first set of parameters further comprises adding a time ΔT to a setup variable and a hold variable.

12. The method of claim 1, wherein the validity analysis is a setup/hold violation analysis.

13. The method of claim 12, wherein a plurality of user-defined parameters are accepted to execute the setup/hold violation analysis.

14. The method of claim 13, wherein the plurality of user-defined parameters include one or more of the following: which channels are to be analyzed, a clocking specification, a violation window search range and a number of violations required to occur prior to analysis completion.

15. Apparatus for deskewing sampled data comprising:
means for accepting a first set of parameters for collecting data samples in a first channel;
means for acquiring data samples from a first location in said first channel;
means for performing a validity analysis of said data samples; and
upon a trigger parameter reaching a predetermined value,
halting the acquisition of new data samples from the first location;
adjusting a value of one or more of the first set of parameters;
acquiring data samples from a second location in said first channel.

16. The apparatus of claim 15, wherein the means for accepting a first set of parameters for collecting data samples in a first channel is a user interface.

17. The apparatus of claim 16, wherein the user interface accepts parameter values selected from the group consisting of what kind of analysis is being performed, which channels are being analyzed, an analysis range, a clocking mode that will be used for analysis, and an analysis quality.

18. The apparatus of claim 15, wherein the interface provides for the selection of optimal sampling points in said first channel for further data collection via an interactive completion signal.

19. The apparatus of claim 15, wherein the validity analysis is a Data Valid Window analysis.

20. The apparatus of claim 15, wherein the step of adjusting a value of one or more of the first set of parameters further comprises adding a time ΔT to a setup and a hold variable.

21. The apparatus of claim 15, wherein the validity analysis is a setup/hold violation analysis.

22. The apparatus of claim 15, wherein the means for performing a validity analysis of said data samples is an auto-deskew manager module.

23. The apparatus of claim 15, wherein the means for performing a validity analysis also sends an interactive completion signal to the means for accepting the first set of parameters.

24. The apparatus of claim 23, wherein the interactive completion signal provides for selection of optimal sampling points in at least said first channel for further data collection.
